(19) United States
(12) Patent Application Publication
(10) Pub. No.: US 2003/0215007 A1
(43) Pub. Date: Nov. 20, 2003

(54) Method for performing an equalisation per carrier in a MC-DMA receiver

(75) Inventor: David Mottier, Rennes Cedex 7 (FR)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 10/417,179

(22) Filed: Apr. 17, 2003

(30) Foreign Application Priority Data
May 2, 2002 (EP) 02 291107.7

(51) Int. Cl. H03K 5/159; H03H 7/30

(52) U.S. Cl. 375/229

(57) ABSTRACT

Method for performing an equalisation in a MC-CDMA receiver, a symbol transmitted to said receiver being spread with a spreading sequence over a plurality (N) of carriers, the signal received by said receiver being decomposed into a plurality of frequency components (rₗ), characterised by estimating (331) relative power values on each of said carriers, calculating (333) a plurality of equalisation coefficients (qₗ) from the estimated relative power values (\hat{P}ₗ, (μ\hat{.}Pₗ)) and multiplying (334₀, . . . ,334_{L-1}) each of said frequency components by one of said equalisation coefficients.

The present invention relates to a method for performing an equalisation per carrier in a MC-CDMA telecommunication system. The present invention relates also to a MC-CDMA receiver implementing such an equalisation method.

Multi-Carrier Code Division Multiple Access (MC-CDMA) combines OFDM (Orthogonal Frequency Division Multiplex) modulation and the CDMA multiple access technique. This multiple access technique was proposed for the first time by N. Yee et al. in the article entitled “Multicarrier CDMA in indoor wireless radio networks” which appeared in Proceedings of PIMRC'93, Vol. 1, pages 109-113, 1993. The developments of this technique were reviewed by S. Hara et al. in the article entitled “Overview of Multicarrier CDMA” published in IEEE Communication Magazine, pages 126-133, December 1997.

Unlike the DS-CDMA (Direct Spread Code Division Multiple Access) method, in which the signal of each user is multiplied in the time domain in order to spread its frequency spectrum, the signature here multiplies the signal in the frequency domain, each element of the signature multiplying the signal of a different sub-carrier.

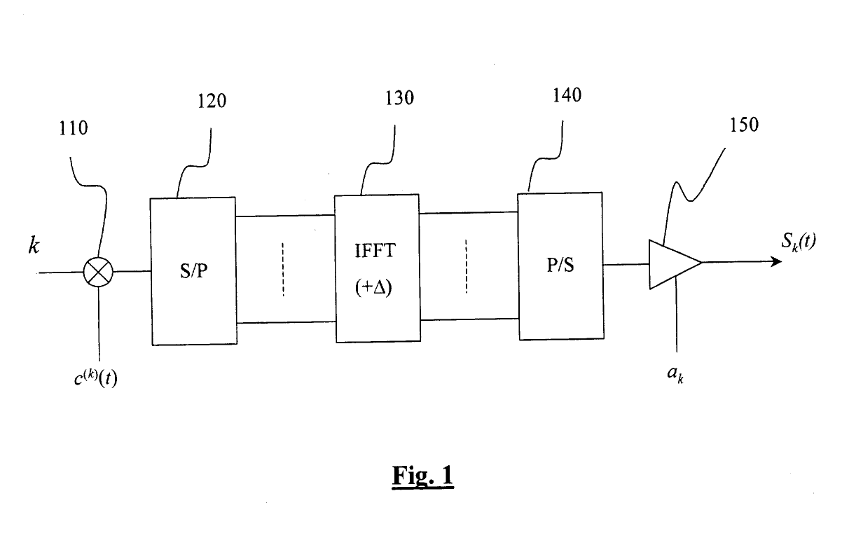

More precisely, FIG. 1 illustrates the structure of an MC-CDMA transmitter for a given user k. We consider here the forward link, i.e. we suppose that the transmitter is located at the base station. Let d^{(k)}(n) be the symbol to be transmitted to user k at time nT, where d^{(k)}(n) belongs to the modulation alphabet. The symbol d^{(k)}(n) is first multiplied at 110 by a spreading sequence or signature of the user, denoted c^{(k)}(t), consisting of N “chips” or signature elements, each “chip” being of duration T_{c}, the total duration of the spreading sequence corresponding to a symbol period T. The results of the multiplication of the symbol d^{(k)}(n) by the different “chips” are converted by the serial to parallel converter 120 into a block of L symbols, where L is in general a multiple of N. Without loss of generality, we assume otherwise specified in the following that N=L and we denote the elements (i.e. the values of the chips) of the sequence for user k:

$${c}_{l}^{( k )} , l = 0 , … , L - 1.$$

The block of L symbols output from 120 is subjected to an inverse fast Fourier transformation (IFFT) in the module 130. In order to prevent intersymbol interference, a guard interval of length typically greater than the duration of the impulse response of the transmission channel, is added to the MC-CDMA symbol. This is achieved in practice by appending a prefix (denoted Δ) identical to the end of the said symbol. After being serialised in the parallel to serial converter 140, the MC-CDMA symbols are amplified at 150 in order to be transmitted over the downlink user channel. The MC-CDMA method can therefore be analysed into a spreading in the spectral domain (before IFFT) followed by an OFDM modulation.

In practice, the user k transmits his data in the form of frames of symbols d^{(k)}(n), each symbol being spread by a real signature c^{(k)}(t), with a duration equal to the symbol period T, i.e. c^{(k)}(t)=0 if t[0,T[ and

$${c}^{( k )} ( t ) = {\sum }_{l = 0}^{L - 1} {c}_{l}^{( k )} δ ( t - l {T}_{c} )$$

if tε[0,T[.

The signal Sₖ(t) at time t transmitted to a user k can therefore be written, if we omit the prefix:

$${S}_{k} ( t ) = {a}_{k} \cdot {\sum }_{l = 0}^{L - 1} {c}^{( k )} ( t ) \cdot {d}^{( k )} ( n ) exp ( j \cdot 2 π ( l t / L ) \qquad ( 1 )$$

where αₖ is the amplitude coefficient of the signal transmitted to user k, assumed to be constant over a transmission frame. Hence, the resulting signal transmitted onto a downlink channel can be expressed, if we omit the prefixes:

$${S}_{k} ( t ) = {\sum }_{k = 0}^{K - 1} {\sum }_{l = 0}^{L - 1} {a}_{k} {c}^{( k )} ( t ) \cdot {d}^{( k )} ( n ) exp ( j \cdot 2 π ( l t / L ) \qquad ( 2 )$$

where K is the number of users.

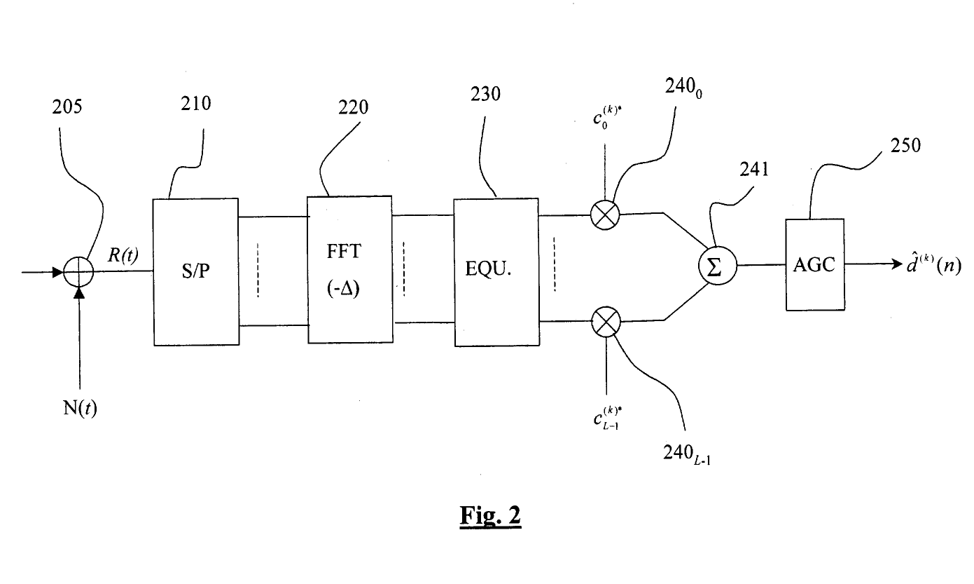

A MC-CDMA receiver for a given user k has been illustrated schematically in FIG. 2. This receiver is known in the literature as single-user detection receiver (or SUD receiver) because the detection takes only into account the symbols transmitted to (or from) the user in question.

After having propagated over the downlink transmission channel, the signal received is demodulated and sampled at the “chip” frequency 1/T_{c}. We assume that the channel is disturbed by an AWGN (Additive White Gaussian Noise) N(t) as illustrated by adder 205 in FIG. 2. The samples of the received signal are then supplied to a serial to parallel converter 210 and stripped from the prefix (Δ) before undergoing an FFT in module 220. The signal on a subcarrier l at the output of 220 can be expressed:

$${r}_{l} ( n ) = {h}_{l} ( n ) {\sum }_{k = 0}^{K - 1} {a}_{k} {c}_{l}^{( k )} {d}^{( k )} ( n ) + {n}_{l} ( n ) \qquad ( 3 )$$

or, equivalently:

$${r}_{l} ( n ) = {h}_{l} ( n ) {\sum }_{k = 0}^{K - 1} {D}_{l}^{( k )} ( n ) + {n}_{l} ( n ) with {D}_{l}^{( k )} = {a}_{k} {c}_{l}^{( k )} {d}^{( k )} ( n ) \qquad ( 4 )$$

where hₗ(n) represents the response of the downlink channel at the frequency of the subcarrier l of the MC-CDMA symbol transmitted at time nT and where nₗ is the noise component on subcarrier l. In the following, the time index n will be omitted for the sake of simplicity.

In MC-CDMA, the presence of the guard interval makes it possible to neglect the intersymbol interference (provided the guard interval is longer than the delay spread of the channel). Hence, for a given subcarrier (hereinafter simply called carrier), the equalisation can be performed by a single tap, i.e. by a multiplication by a complex coefficient. Such equalisation, also called per carrier equalisation consists in applying one of the known equalisation methods e.g. ZF (Zero Forcing), MMSE (Minimum Mean Square Error), independently on each carrier.

The equalisation coefficients are denoted

$${q}_{l}^{( k )} , l = 0 , … , L - 1$$

for the SUD receiver dedicated to the user k. The samples in the frequency domain are respectively multiplied by the equalisation coefficients

$${q}_{l}^{( k )}$$

in 230. It is assumed in the following that a MMSE criterion is chosen, i.e. that a MMSE equalisation per carrier is used.

In such instance, the equalisation coefficients are given by:

$${q}_{l}^{( k )} = \frac{{a}_{k} {\hat{h}}_{l}^{*}}{{\vert {\hat{h}}_{l} \vert}^{2} \cdot {\sum }_{k = 0}^{K - 1} {a}_{k}^{2} + {σ}_{l}^{2}} \qquad ( 5 )$$

where σₗ is the variance of the noise component on carrier l, ĥₗ is an estimate of hₗ and .* denotes the complex conjugate. The estimate ĥₗ is generally obtained by transmitting pilot symbols at regular intervals over the transmission channel.

In practice, since the multiplying coefficient αₖ appearing at the numerator of (5) is the same for all the carriers, it can be omitted and the compensation for amplitude coefficient variations is ensured by an automatic gain control (AGC) as described further below. If an AGC is used the equalisation coefficients may therefore be expressed as:

$${q}_{l}^{( k )} = \frac{{\hat{h}}_{l}^{*}}{{\vert {\hat{h}}_{l} \vert}^{2} \cdot {\sum }_{k = 0}^{K - 1} {a}_{k}^{2} + {σ}_{l}^{2}} \qquad ( {5}^{′} )$$

After equalisation, the frequency components are despread i.e. they are multiplied by the conjugated signature of the user k in 240₀, . . . ,240_{L-1} before being added in 241. The result is then normalised by automatic gain control 250 to give an estimation \hat{d}ₖ(n) of the transmitted symbol dₖ(n). In fact \hat{d}ₖ(n) is a decision variable which can be used as such (soft detection) or subjected to a hard decision (not shown). For the sake of simplicity, we keep hereinafter the same notation in both cases.

The calculation of the equalisation coefficients according to equation (5) or (5′) necessitates to know in particular the number of users K and the amplitude coefficients αₖ. Since the receiver cannot determine these values, they have to be sent at regular intervals by the MC-CDMA transmitter over the transmission channel, at the expense of the payload.

The problem underlying the invention is to propose a method for performing an equalisation per carrier which uses less transmission resources than in the prior art.

This problem is solved by the equalisation method defined in claim 1 Advantageous embodiments of the invention are set out in the dependent claims. The invention is also defined by a MC-CDMA receiver as set out in claim 6 or 7.

The characteristics of the invention will emerge from a reading of the following description given in relation to the accompanying figures, amongst which:

FIG. 1 depicts schematically the structure of a MC-CDMA transmitter known from the state of the art;

FIG. 2 depicts schematically the structure of a MC-CDMA receiver using a MMSE per carrier equalisation known from the state of the art;

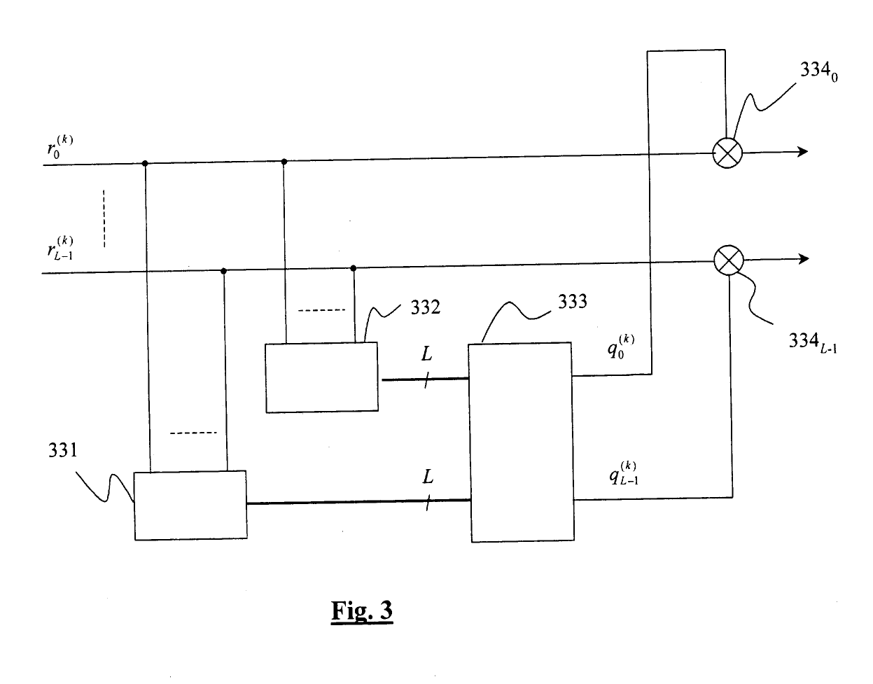

FIG. 3 depicts schematically a method for obtaining equalization coefficients used in the equalisation method according to the invention;

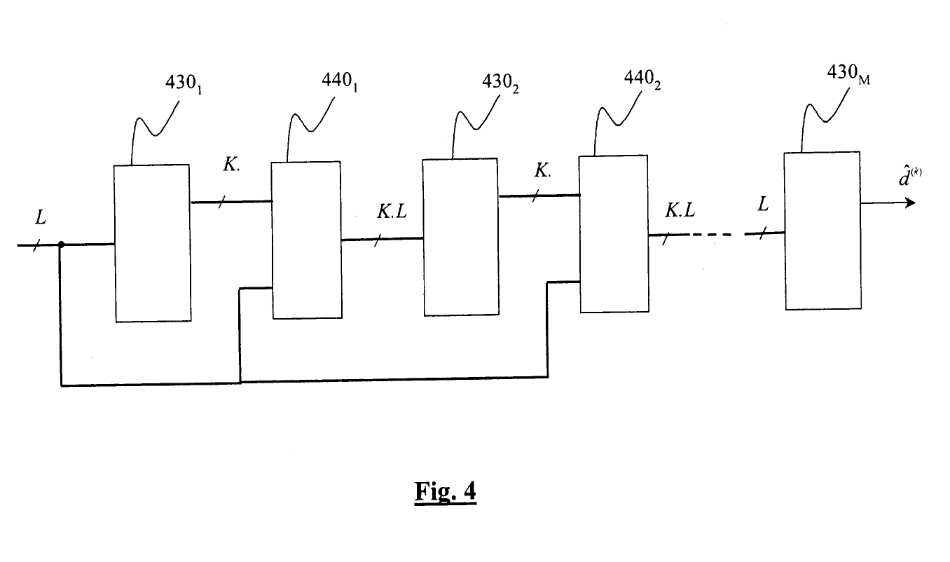

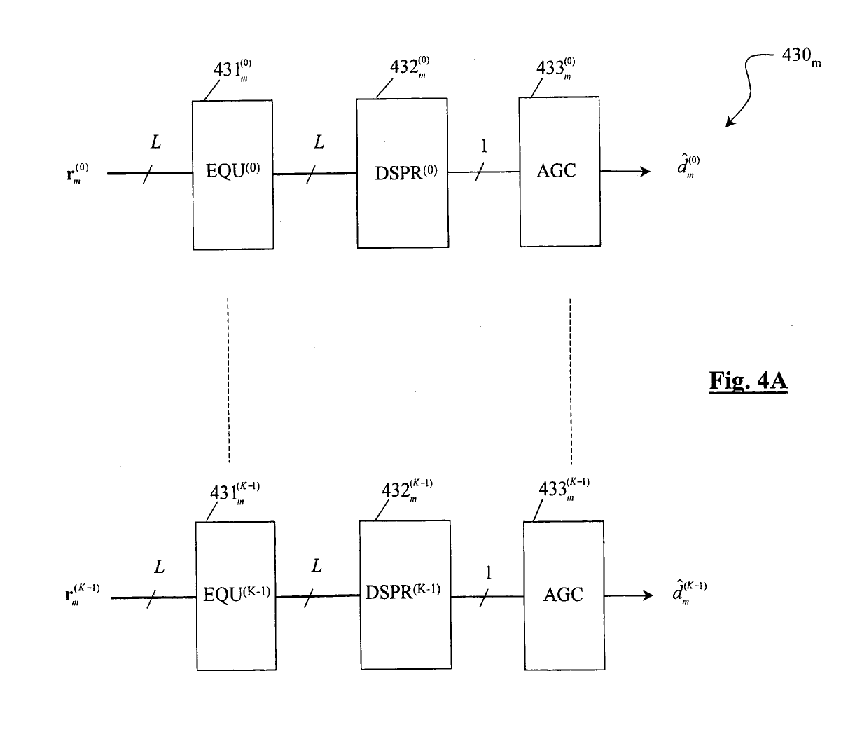

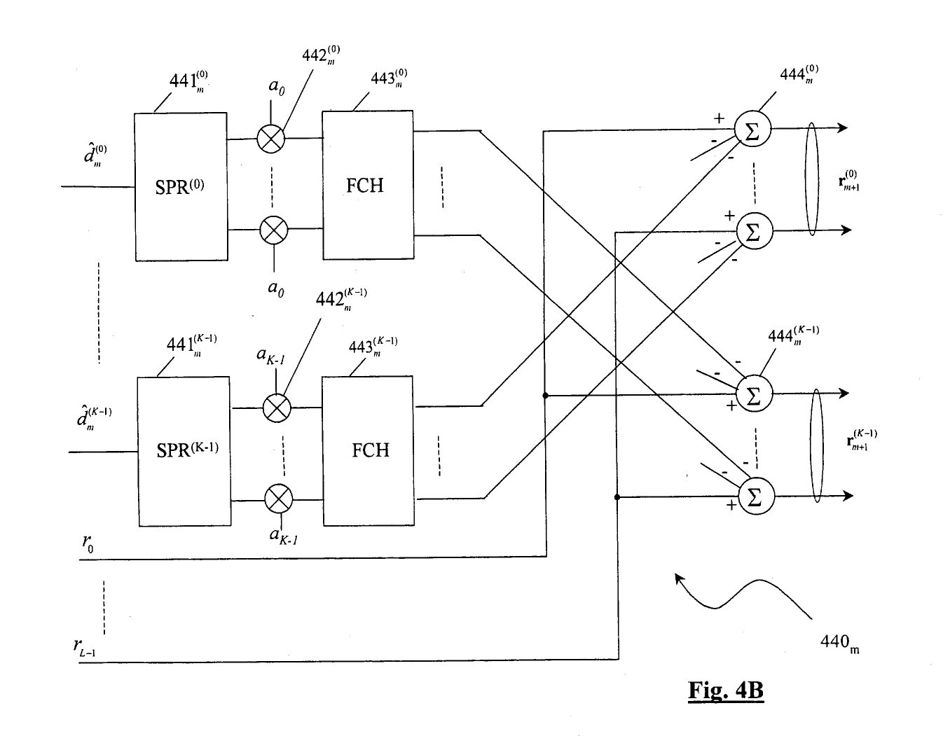

FIG. 4 depicts schematically the structure of a MC-CDMA receiver with parallel interference cancellation;

FIG. 4A depicts a first stage of the MC-CDMA receiver illustrated in FIG. 4;

FIG. 4B depicts a second stage of the MC-CDMA receiver illustrated in FIG. 4;

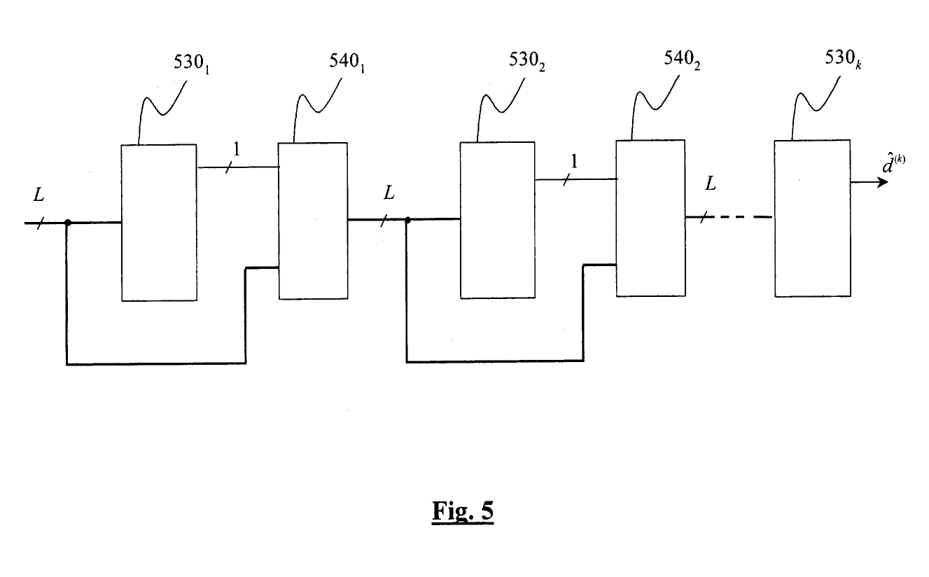

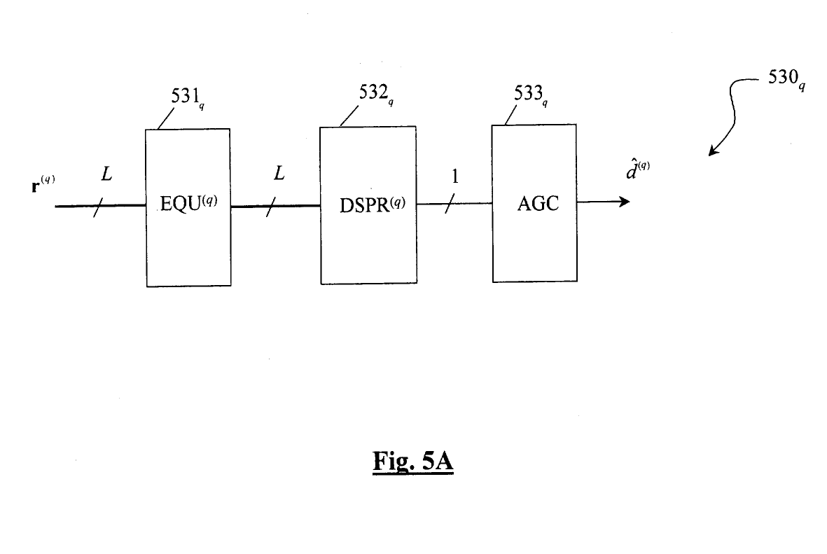

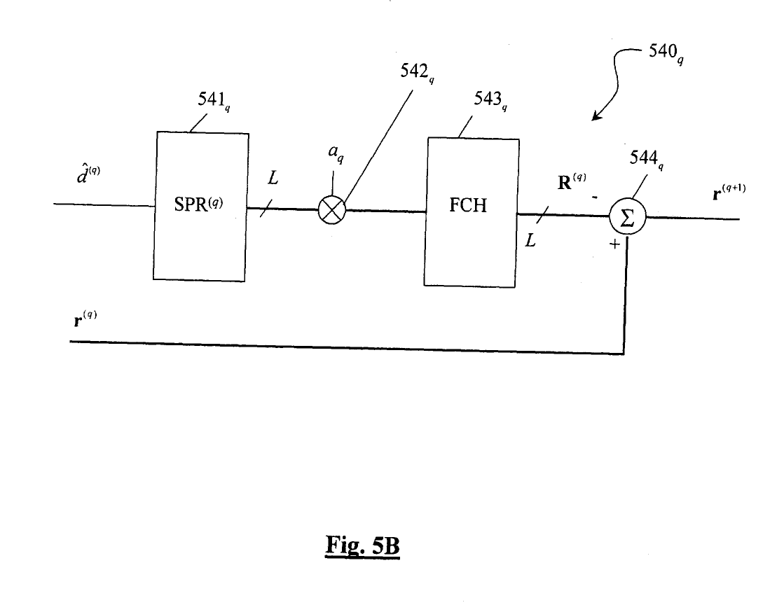

FIG. 5 depicts schematically the structure of a MC-CDMA receiver with serial interference cancellation;

FIG. 5A depicts a first stage of the MC-CDMA receiver illustrated in FIG. 5;

FIG. 5B depicts a second stage of the MC-CDMA receiver illustrated in FIG. 5.

The basic idea underlying the invention is to derive the value of the denominator of the expression (5) or (5′) defining the equalisation coefficients from estimates of the power received on the different carriers.

We refer back to the context of a MC-CDMA receiver with per carrier equalisation where the equalisation coefficients are determined to satisfy the MMSE criterion. If an automatic gain control is used as in FIG. 2, the equalisation coefficients can be determined by:

$${q}_{l}^{( k )} = \frac{{h}_{l}^{*}}{\vert {h}_{l} {\vert}^{2} \cdot {\sum }_{k = 0}^{K - 1} {a}_{k}^{2} + {σ}_{l}^{2}} \qquad ( 6 )$$

On the other hand, the power received on a given carrier can be expressed as follows:

$${P}_{l} = {\vert {h}_{l} \vert}^{2} \cdot {\sum }_{k = 0}^{K - 1} E ( \vert {D}_{k} {\vert}^{2} ) + {σ}_{l}^{2} \qquad ( 7 )$$

where E denotes the mathematical expectation. The first term represents the signal power and the second term is the noise power on the carrier. Without loss of generality, we may assume that the emitted symbols and the spreading codes are normalised:

$${P}_{l} = \vert {h}_{l} {\vert}^{2} \cdot {\sum }_{k = 0}^{K - 1} {a}_{k}^{2} + {σ}_{l}^{2} \qquad ( 8 )$$

The power received on a given carrier can be estimated by:

$${\hat{P}}_{l} = \frac{1}{{N}_{s}} \cdot {\sum }_{n = 1}^{{N}_{s}} {\vert {r}_{l} ( n ) \vert}^{2} \qquad ( 9 )$$

where Nₛ is the number of consecutive symbols taken into account in the averaging process. It should be understood that any estimate suitable for estimating the power on the different carriers can be used. For example, the power estimation can be performed by filtering the samples |rₗ(n)|² with a low-pass filtering of the recursive type as:

\hat{P}ₗ(n)=(1−α).\hat{P}ₗ(n−1)+α.|rₗ(n)|² (10)

where α is a forgetting factor which is preferably taken equal to 2^{-P} and P is a positive integer.

From the expressions (6) and (8), the equalisation coefficients can be calculated as follows:

$${q}_{l}^{( k )} = \frac{{\hat{h}}_{l}^{*}}{{\hat{P}}_{l}} \qquad ( 11 )$$

More generally, it suffices to have estimates proportional to the channel coefficients hₗ and /or proportional to the power values Pₗ. In other words, the channels coefficients and/or the power values can be simply be estimated relatively to each other. If λ and μ are the proportionality factors for the channel coefficient estimate and the power estimate respectively, we may choose as equalisation coefficients:

$${q}_{l}^{( k )} = \frac{{( λ \cdot {\hat{h}}_{l} )}^{*}}{( μ \cdot {\hat{P}}_{l} )} \qquad ( 12 )$$

where (λ\hat{.}hₗ) and (μ\hat{.}Pₗ) are the estimates proportional to the channel coefficients and the power values respectively. The proportionality factors λ and μ have no influence on the equalisation since they are common to all the carriers. They may also be time dependent since the automatic gain mentioned above would compensate for such variations.

FIG. 3 illustrates schematically an equalisation method according to the invention.

The complex values rₗ, l=0, . . . ,L−1, relative to the different carriers at the output of the FFT module (i.e. module 220 in FIG. 2) are directed to the power estimation module 331 and the channel estimation module 332. The power estimation module estimates the power received by the different carriers (possibly multiplied by a common proportionality factor) e.g. according to expression (9) or (10). The channel estimation module estimates the channel coefficients hₗ relative to the different carriers (possibly multiplied by a common proportionality factor). For example, according to a channel estimation method known as such, pilot symbols are periodically sent by the MC-CDMA transmitter and the channel coefficients are determined from the complex values rₗ of the corresponding received symbols.

The equalisation coefficients

$${q}_{l}^{( k )}$$

are obtained by division in the module 333, in accordance with equation (11) or (12). The complex values rₗ, l=0, . . . ,L−1 are then respectively multiplied by the multipliers 334₀, . . . ,334_{L-}1 with the equalisation coefficients

$${q}_{l}^{( k )}$$

to produce equalised signals.

It is important to note that if the symbols d^{(k)}(n) for the user k are spread over a subset of N (where N is preferably a submultiple of L), it suffices to calculate the equalisation coefficients for this subset of carriers. Hence, the estimation of the channel coefficients and the power values can be limited to this subset.

According to a first application of the invention, the equalisation method illustrated in FIG. 3 is implemented in the equalisation module 230 of the MC-CDMA receiver of FIG. 2. The equalised signals are then despread and the despread result is subjected to an automatic gain control.

FIG. 4 illustrates the structure of a MC-CDMA receiver with parallel interference cancellation (PIC) associated to a given user k. This receiver is known as a multi-user detection receiver (or MUD receiver) because the detection takes also into account the symbols transmitted by the MC-CDMA transmitter to the users other than the one considered (k). In FIG. 4, only the part of the receiver downstream from the FFT module has been represented. It comprises a series of M identical first stages 430ᵢ, m=1, . . . ,M alternating with a series of M−1 identical second stages 440ₘ, m=1, . . . M−1, the output of a first stage 430ₘ being the input of the subsequent second stage 440ₘ and the output of a second stage 440ₘ being the input of the subsequent first stage 430ₘ₊₁. The L complex values rₗ, l=0, . . . ,L−1, output by the FFT are provided to each of second stages 440ₘ. Finally, the stage 430_{M} outputs an estimate of the symbol transmitted to the user k in question. It should be understood that the cascaded stages can be equivalently replaced by a single stage performing a series of iterations.

FIG. 4A illustrates schematically the process carried out in a first stage 430ₘ. It receives K interference cleared vectors

$${r}_{( m )}^{( q )} , q = 0 , … K - 1$$

each having L components corresponding to the L carriers. A vector

$${r}_{( m )}^{( q )}$$

represents the frequency components of a MC-CDMA symbol transmitted to user q in which the contribution due to the other users has been removed as shown further below. The vectors

$${r}_{( 1 )}^{( q )}$$

of the first stage 430₁ are all identical and their components are equal to the L complex values, provided by the FFT. The L frequency components of each of the vectors

$${r}_{( m )}^{( q )}$$

are equalised by the module

$${431}_{m}^{( q )} ,$$

then despread in the module

$${432}_{m}^{( q )}$$

by the conjugate of the spreading code of user q and the despread result is subjected to an automatic gain control in

$${433}_{m}^{( q )} .$$

The output of

$${433}_{m}^{( q )} ,$$

denoted

$${\hat{d}}_{m}^{( q )}$$

is used as such (soft decision) or subject to a hard or non linear decision (not shown), channel decoding and subsequent reencoding, the same notation

$${\hat{d}}_{m}^{( q )}$$

being retained for all cases.

According to a second application of the invention the equalisation method of illustrated in FIG. 3 is implemented in the equalisation modules

$${431}_{m}^{( q )} , q = 0 , … , K - 1.$$

It should be understood that the calculation of the power values \hat{P}ₗ in the equalisation modules

$${431}_{1}^{( q )}$$

is the same for q=0, . . . ,K−1. The power calculation can therefore be shared by the K modules of the first stage.

FIG. 4B illustrates schematically the process carried out in a second stage 440ₘ. This stage receives the K estimates

$${\hat{d}}_{m}^{( q )} , q = 0 , … , K - 1$$

output by the preceding stage 430ₘ and the L complex values rₗ, l=0, . . . ,L−1 output from the FFT. Each estimate

$${\hat{d}}_{m}^{( q )}$$

is spread by the spreading code of the corresponding user q in module

$${441}_{m}^{( q )} .$$

The spread signal can be expressed as a vector of N frequency components (as mentioned in the introductory part, although N has been assumed to L for the sake of simplicity, sub-multiple values of L can equally be envisaged). The components of the spread signal are then multiplied in

$${442}_{m}^{( q )}$$

by the amplitude coefficient a_{q} before being filtered in the frequency domain by a transmission channel equivalent filter

$${443}_{m}^{( q )} .$$

Advantageously, the transmission channel equivalent filter uses the estimates of the channel coefficients which have been determined at the preceding stage 430ₘ in the equalisation module

$${431}_{m}^{( q )} .$$

The transmission channel equivalent filter may also be based upon an average over the estimates of the channel coefficients determined by the different equalisation modules

$${431}_{m}^{( q )} , q = 0 , … , K - 1 ,$$

at the preceding stage 430ₘ, since all these estimates relate to the same (downlink) transmission channel. The components

$${R}_{l , m}^{( q )}$$

output by

$${443}_{m}^{( q )}$$

may be written:

$${R}_{l , m}^{( q )} = {a}_{q} {\hat{h}}_{l} {c}_{l}^{( q )} {\hat{d}}_{m}^{( q )} \qquad ( 13 )$$

where ĥₗ are the estimates of the channel coefficients. The component

$${R}_{l , m}^{( q )}$$

reflects the contribution of user q to the complex value rₗ, i.e. the multi access interference (MAI) due to user q. Denoting

$${R}_{m}^{( q )}$$

the vector of components

$${R}_{l , m}^{( q )} , l = 0 , … , L - 1$$

and r the vector of components rₗ, l=0, . . . ,L−1, the interference cleared vector

$${r}_{m + 1}^{( {q}^{′} )}$$

is obtained by subtracting (in

$${444}_{m}^{( {q}^{′} )}$$

) from r the contribution of the users q≠q′, i.e.:

$${r}_{m + 1}^{( {q}^{′} )} = r - {\sum }_{{q = 0}_{q \neq {q}^{′}}}^{K - 1} {R}_{m}^{( q )} \qquad ( 14 )$$

and these K interference cleared vectors are output to the next stage 430ₘ₊₁.

From one stage to the next, the evaluation of the MAI is refined and the estimation of the transmitted symbols

$${\hat{d}}_{m}^{( q )}$$

is improved. At the last stage 430_{M}, only the estimation of the symbol transmitted to the user k of interest is exploited.

It should be noted that the MC-CDMA receiver of FIG. 4 requires the knowledge of the number K of users, their respective spreading sequences and amplitude coefficients a_{q} for the parallel interference cancellation (e.g. in

$${442}_{m}^{( q )}$$

). However, it is important to note that, advantageously, the coefficients a_{q} used for multiplication in

$${442}_{m}^{( q )}$$

can be estimated (in relative values) by taking the AGC coefficients respectively used in the AGC modules

$${443}_{m}^{( q )} .$$

They therefore need not be sent by the MC-CDMA transmitter.

FIG. 5 illustrates the structure of a MC-CDMA receiver with serial interference cancellation (SIC) associated to a user k. This receiver is a multi-user detection receiver (or MUD receiver) because the symbols transmitted to users other than k are estimated for the purpose of MAI removal.

Here again, only the part of the receiver downstream from the FFT module has been represented. The receiver comprises a series of identical first stages 530_{q} alternating with a series of identical second stages 540_{q}, the output of a first stage 530_{q} being the input of the subsequent second stage 540_{q} and the output of a second stage 540_{q} being the input of the subsequent first stage 530_{q+1}. A couple of first and second stages 530_{q}, 540_{q} is related to a user q, the first stage 530_{q} estimating the symbol transmitted to said user, the associated second stage 540_{q} estimating the MAI due to said user. The number of stages depends upon the number of users the MAI of which is to be removed. Advantageously, the users are ranked by decreasing received power at the MC-CDMA receiver side so that the symbol detection and the MAI estimation starts with the most interfering ones. The process terminates in 530ₖ with the estimation of the symbol transmitted to the user k in question.

FIG. 5A depicts schematically the process carried out in a first stage 530_{q}. It receives an interference cleared vector r^{(q)} where the MAI due to the q most energetic users has been removed. The first stage 530₀ directly receives the vector r⁽⁰⁾=r of components rₗ, l=0, . . . ,L−1, output from the FFT. The L frequency components of each of the vectors r^{(q)} are equalised in the module 531_{q}, then despread in the module 532_{q} by the conjugate of the spreading code of user q and the despread result is subjected to an automatic gain control in 533_{q}. The output of 533_{q}, denoted \hat{d}^{(q)} is used as such (soft decision) or subject to a hard or non-linear decision (not shown), channel decoding and subsequent reencoding, the same notation \hat{d}^{(q)} being retained for all cases.

According to a third application of the invention, the equalisation method illustrated in FIG. 3 is implemented in the equalisation modules 531^{(q)}.

FIG. 5B illustrates schematically the process carried out in a second stage 540_{q}. This stage receives the symbol estimate \hat{d}^{(q)} on the one hand and the interference cleared vector r^{(q)} on the other hand. The symbol estimate \hat{d}^{(q)} is spread by the spreading code of the user q in module 541_{q}. The spread signal can be expressed as a vector of N frequency components (assumed equal to L for the sake of simplicity) The components of the spread signal are then multiplied in 542_{q} by the amplitude coefficient a_{q} before being filtered in the frequency domain by a transmission channel equivalent filter 543_{q}. Advantageously, the transmission channel equivalent filter uses the estimates of the channel coefficients which have been determined at the preceding stage 530_{q} in the equalisation module 531_{q}.

The components

$${R}_{l}^{( q )}$$

output by 543_{q} may be written:

$${R}_{l}^{( q )} = {a}_{q} {\hat{h}}_{l} {c}_{l}^{( q )} {\hat{d}}^{( q )} \qquad ( 15 )$$

where ĥₗ are the estimates of the channel coefficients. The component

$${R}_{l}^{( q )}$$

reflects the contribution of user q to the complex value rₗ, i.e. the multi access interference (MAI) due to user q. Denoting R^{(q)} the vector of components

$${R}_{l}^{( q )} , l = 0 , … , L - 1$$

the interference cleared vector r^{(q+1)} is obtained by subtracting (in 544_{q}) from r^{(q)} the MAd due to the user q, i.e.:

r^{(q+1)}=r^{(q)}−R^{(q)} (16)

Here again, the MC-CDMA receiver of FIG. 5 requires the knowledge of the number K of users, their respective spreading sequences and amplitude coefficients a_{q} for the serial interference cancellation (e.g. in

$${542}_{m}^{( q )} ) .$$

). However, it is important to note that, if the variations of the amplitude coefficients a_{q} are small from one MC-CDMA symbol to the next, the coefficients a_{q} in 542^{(q)} can be advantageously estimated (in relative values) by taking the AGC coefficients respectively used in the AGC modules 543^{(q)} for the previous symbol. The amplitude coefficients therefore need not be sent by the MC-CDMA transmitter.

Although the structure of the MC-CDMA receivers using the equalisation method according to the invention have been essentially described in terms of functional modules e.g. filters or multipliers, it goes without saying that all or part of these devices can be implemented by means of a single processor either dedicated for fulfilling all the functions depicted or in the form of a plurality of processors either dedicated or programmed for each fulfilling one or some of said functions.

1) Method for performing an equalisation in a MC-CDMA receiver, the symbols transmitted to said receiver being spread with a spreading sequence over a plurality (N) of carriers, the signal received by said receiver being decomposed into a plurality of frequency components (rₗ), characterised by estimating (331) relative power values on each of said carriers, calculating (333) a plurality of equalisation coefficients (qₗ) from the estimated relative power values (\hat{P}ₗ,(μ\hat{.}Pₗ)) and multiplying (334₀, . . . ,334_{L-}1) each of said frequency components by one of said equalisation coefficients.

2) Method for performing an equalisation in a MC-CDMA receiver according to claim 1, characterised by estimating (332), at the frequencies of said carriers, the relative channel coefficients (ĥₗ,(λ\hat{.}hₗ)) of the transmission channel over which said symbols have propagated.

3) Method for performing an equalisation in a MC-CDMA receiver according to claim 2, characterised that for a given carrier an equalisation coefficient is obtained by dividing the estimated relative channel coefficient at the carrier frequency with the estimated relative power value on that carrier.

4) Method for performing an equalisation in a MC-CDMA receiver according to any of preceding claims, characterised in that the relative power value on a carrier is estimated by low pass filtering samples of the square value of the component of said received signal at the frequency of said carrier.

5) Method for performing an equalisation in a MC-CDMA receiver according to claim 4, characterised in that the relative power value on a carrier is estimated by averaging samples of the square value of the component of said received signal at the frequency of said carrier.

6) Multi-carrier CDMA receiver in a MC-CDMA telecommunication system characterised by comprising decomposing means for decomposing a received signal into a plurality of frequency components carried by a plurality of carriers, equalising means for multiplying each of said frequency components with an equalisation coefficient, characterised in that said equalising means further comprise means for estimating relative power values on each of said carriers and means for calculating the equalisation coefficients from the estimated relative power values

7) Multi-carrier CDMA receiver in a MC-CDMA telecommunication system, said receiver being dedicated to a user of said system, characterised in that it comprises decomposing means for decomposing a received signal into a plurality of frequency components carried by a plurality of carriers, interference removing means for removing from each of said frequency components the contribution due to signals transmitted to at least another user of said system, said interference removing means producing interference cleared frequency components carried by said plurality of carriers, said receiver further comprising equalising means for multiplying each of said removed frequency components with an equalisation coefficient, said equalising means comprising means for estimating relative power values on each of said carriers after interference removal and means for calculating the equalisation coefficients from the estimated relative power values.
